(19) United States
(12) Patent Application Publication
(10) Pub. No.: US 2009/0208887 A1
(43) Pub. Date: Aug. 20, 2009

(54) REMOVING SOLUTION FOR PHOTOSENSITIVE COMPOSITION

(75) Inventors: Masato Kaneda, Yamaguchi (JP); Kouichi Terao, Yamaguchi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., TOKYO (JP)

(21) Appl. No.: 11/993,984

(22) PCT Filed: Jul. 11, 2006
(86) PCT No.: PCT/JP2006/314131

§ 371 Date: Dec. 27, 2007

Related U.S. Application Data
(60) Provisional application No. 60/702,625, filed on Jul. 27, 2005.

(30) Foreign Application Priority Data
Jul. 19, 2005 (JP) 2005-208478

(51) Int. Cl. G03F 7/00

(52) U.S. Cl. 430/331

(57) ABSTRACT

A removing solution for photosensitive composition for removal of pigment-containing photosensitive compositions, comprising an alicyclic ketone, an alkylene glycol monoalkyl ether and/or alcohol, and optionally an acetic acid ester. The removing solution has excellent photosensitive composition removing performance.

### CROSS-REFERENCE TO RELATED APPLICATION

This application is an application filed under 35 U.S.C. § 111(a) claiming benefit of priority pursuant to 35 U.S.C. § 119(e) (1) of the filing date of the Provisional Application 60/702,625 filed Jul. 27, 2005, pursuant to 35 U.S.C. § 111(b).

### TECHNICAL FIELD

The present invention relates to a removing solution for photosensitive composition. In particular, the invention relates to a removing solution for removal of an uncured photosensitive composition film coated on the periphery, edges or back side of a substrate or for removal of an uncured photosensitive composition attached to the surface of an apparatus member or an equipment, during the step of forming a photosensitive composition film on a glass panel, semiconductor wafer or the like.

The removing solution for photosensitive composition of the invention is particularly useful for removal of a residual uncured pigment-containing photosensitive composition film on the periphery, edges or back side of a substrate or for removal of an uncured pigment-containing photosensitive composition attached to the surface of an apparatus member or an equipment, in the step of forming a photosensitive composition film on the substrate for manufacture of a color filter used for a liquid crystal device, an organic EL device or an image sensor.

### BACKGROUND ART

Photosensitive composition patterns are ordinarily formed using lithographic techniques in manufacturing processes for flat panel displays such as liquid crystal devices, organic EL devices or plasma displays or for semiconductors.

RGB or resin black matrix pattern forming methods used for manufacture of color filters used in liquid crystal devices, organic EL devices and image sensors include pigment dispersion methods, dyeing methods, printing methods and electrodeposition methods. Pigment dispersion methods accomplish patterning of different colors by photolithography using a photosensitive composition containing a pigment, and because they yield stable colored films they are suitable for manufacture of color filters. When a photosensitive composition film is formed on a substrate by such a method, a process for coating the pigment-containing photosensitive composition onto the substrate is included, and known coating methods therefor include spin coating, slit coating, wire bar coating, roll coating, dip coating, spray coating and combinations of these.

In the case of spin coating, removal of swelling portions of the photosensitive composition on the periphery or edges of the substrate after coating of the photosensitive composition, or removal of the photosensitive composition attached to the back side thereof, is usually accomplished by rinsing treatment with a removing solution for photosensitive composition, known as edge rinsing or back rinsing. Photosensitive composition removal with a removing solution for photosensitive composition is also carried out in so-called cup rinsing, which is a step of removing the photosensitive composition that has splashed out in a coater-cup.

The coating process for the photosensitive composition during the manufacture of a color filter may be coating of the photosensitive composition by slit coating, coating using a wire bar, or coating with a roll coater instead of the aforementioned spin coating, but in all of these methods the coating of the photosensitive composition is followed by removal of the unnecessary photosensitive composition on all or portions of the coating apparatus, such as the slit nozzle or wire bar.

In addition, it is also sometimes necessary to remove the photosensitive composition attached to members of the coating apparatus such as apparatus tubes used for transport of the photosensitive composition. In most cases, removal of the photosensitive composition is accomplished by cleaning with a removing solution.

Residue of the photosensitive composition components is a problem in all removal steps for photosensitive compositions attached to such substrates or apparatuses. Pigment-containing photosensitive compositions used in the manufacture of color filters, i.e., color resists used for RGB formation or black resists used for resin black matrix formation, tend to leave residues of the pigment components on the substrate or apparatus surfaces, and even when present in small amounts these constitute foreign inclusions which cause increase of the defect ratio in color filter manufacturing or color purity degradation or reduced contrast of the color filter. With the increasing requirements for larger sizes, higher precision and lower cost of substrates employed in color displays in recent years, it is becoming even more important to avoid photosensitive composition component residue that can affect the performance and yields of color filters.

Conventional photosensitive composition removing agents are generally glycol ethers or their esters or mixtures thereof (for example, see Japanese Unexamined Patent Publication No. 11-44960 and Japanese Patent No. 3125917), but when these are applied for cleaning and removal of the aforementioned color resists, the resist-removing property is inadequate and the removing solution must be used in a large amount, also resulting in production of removal residue.

Pigment-containing coloring compositions are also removed by methods employing solvent components used in photosensitive compositions or components contained in photosensitive compositions such as surfactants or dispersing agents (for example, see Japanese Unexamined Patent Publication No. 2000-273370), but when solvent components in photosensitive compositions are used alone as the cleaning agents, the pigments tend to precipitate and an adequate cleaning effect cannot be achieved. In addition, when components contained in photosensitive compositions such as surfactants or dispersing agents are added to cleaning solution compositions, the components tend to remain as vaporization residue on substrates or apparatus members, thus requiring a further cleaning step, and they essentially cannot be used for removal of the photosensitive composition from the edges or back sides of substrates which preferably should not have vaporization residue.

### DISCLOSURE OF INVENTION

It is an object of the present invention to provide a removing solution for photosensitive composition with excellent ability to remove photosensitive compositions.

The invention provides, in particular, a removing solution which is effective for removal of a residual pigment-containing photosensitive composition film coated on the periphery, edges or back side of a substrate or for removal of a pigment-containing photosensitive composition attached to the surface of an apparatus member or an equipment, during the step of forming a photosensitive composition film on a liquid crystal device, an organic EL device, an image sensor or the like.

In some parts of the present specification, the alicyclic ketone will be referred to as component 1, the alkylene glycol monoalkyl ether or alcohol will be referred to as component 2 and the acetic acid ester will be referred to as component 3.

The present inventors have conducted much diligent research toward overcoming the aforementioned problems. As a result, it was discovered that the ability to clean and remove pigment-containing photosensitive compositions is improved by using a removal solution having a specified composition, and the present invention has thereupon been completed.

Specifically, the invention comprises the following aspects.

[1] A removing solution for photosensitive composition which is a removing solution for a photosensitive composition containing a pigment, characterized by comprising

(1) 99-30 mass % of an alicyclic ketone and

(2) 1-70 mass % of at least one compound selected from alkylene glycol monoalkyl ethers and alcohols.

[2] A removing solution for photosensitive composition which is a removing solution for a photosensitive composition containing a pigment, characterized by comprising

(1) 80-30 mass % of an alicyclic ketone,

(2) 60-10 mass % of at least one compound selected from alkylene glycol monoalkyl ethers and alcohols and

(3) 40-10 mass % of an acetic acid ester.

[3] A removing solution for photosensitive composition according to [1] or [2] above, wherein the alicyclic ketone is one or more selected from the group consisting of cyclohexanone, cyclopentanone and methylcyclohexanone.

[4] A removing solution for photosensitive composition according to any one of [1] to [3] above, wherein the alkylene glycol monoalkyl ether is one or more selected from the group consisting of ethylene glycol monomethyl ether, ethylene glycol monoethyl ether, diethylene glycol monomethyl ether, diethylene glycol monoethyl ether, propylene glycol monomethyl ether, propylene glycol monoethyl ether, dipropylene glycol monomethyl ether, 3-methoxybutanol and 3-methyl-3-methoxybutanol, and the alcohol is one or more selected from the group consisting of 1-propanol, 2-propanol, 1-butanol, 2-butanol and t-butanol.

[5] A removing solution for photosensitive composition according to any one of [2] to [4] above, wherein the acetic acid ester is one or more selected from the group consisting of ethyl acetate, n-propyl acetate, isopropyl acetate, n-butyl acetate, n-amyl acetate, isoamyl acetate and sec-amyl acetate.

[6] A removing solution for photosensitive composition according to any one of [1] to [5] above, which is used for removal of an acrylic photosensitive composition containing a pigment.

[7] A removing solution for photosensitive composition according to any one of [1] to [6] above, which is used for removal of a photosensitive composition containing a pigment prior to exposure to light.

[8] An apparatus in which a photosensitive composition containing a pigment is removed using a removing solution for photosensitive composition according to any one of [1] to [7] above.

[9] A color filter obtained by an apparatus according to [8] above.

[10] A device equipped with a color filter according to [9] above.

[11] A substrate that has been treated for removal of a photosensitive composition containing a pigment using a removing solution for photosensitive composition according to any one of [1] to [7] above.

The removing solution for photosensitive composition of the invention can be effectively used for removal of a residual pigment-containing photosensitive composition film coated on the periphery, edges or back side of a substrate during the step of forming a photosensitive composition film on a liquid crystal device or organic EL device, image sensor or the like, or for removal of a pigment-containing photosensitive composition attached to the surface of an apparatus member or an equipment.

### BEST MODE FOR CARRYING OUT THE INVENTION

Preferred modes of the removing solution for photosensitive composition of the invention will now be explained.

The removing solution for photosensitive composition of the invention is used for removal of pigment-containing photosensitive compositions, and it comprises an alicyclic ketone (component 1) and an alkylene glycol monoalkyl ether and/or alcohol (component 2).

The alicyclic ketone (component 1) used for the invention is preferably used as a major component of the removing solution for photosensitive composition, because of the high solubility of the resin component in the photosensitive composition. As specific examples there may be mentioned cyclohexanone, cyclopentanone, methylcyclohexanone and methylcyclopentanone, and at least one of these compounds can be used, although the invention is not limited to these.

Among these, cyclohexanone, cyclopentanone and methylcyclohexanone are particularly preferred from the standpoint of high solubility in the photosensitive composition, ready availability and safety.

The alkylene glycol monoalkyl ethers and alcohols (component 2) used for the invention are preferably used as a major component of the removing solution for photosensitive composition because its admixture with the alicyclic ketone increases the solubility of the resin component of the photosensitive composition.

As specific examples of alkylene glycol monoalkyl ethers there may be mentioned ethylene glycol monomethyl ether, ethylene glycol monoethyl ether, ethylene glycol mono-n-propyl ether, ethylene glycol isopropyl ether, ethylene glycol mono-n-butyl ether, diethylene glycol monomethyl ether, diethylene glycol monoethyl ether, diethylene glycol monopropyl ether, diethylene glycol mono-n-butyl ether, propylene glycol monomethyl ether, propylene glycol monoethyl ether, propylene glycol monopropyl ether, propylene glycol mono-n-butyl ether, dipropylene glycol monomethyl ether, tripropylene glycol monomethyl ether, 3-methoxybutanol and 3-methyl-3-methoxybutanol, and at least one of these compounds can be used, although the invention is not limited to these.

Particularly preferred among these are ethylene glycol monomethyl ether, ethylene glycol monoethyl ether, diethylene glycol monomethyl ether, diethylene glycol monoethyl ether, propylene glycol monomethyl ether, propylene glycol monoethyl ether, dipropylene glycol monomethyl ether, 3-methoxybutanol and 3-methyl-3-methoxybutanol, and especially propylene glycol monomethyl ether, 3-methoxybutanol and 3-methyl-3-methoxybutanol, from the standpoint of high solubility in the photosensitive composition, ready availability and safety.

As specific examples of alcohols there may be mentioned methanol, ethanol, 1-propanol, 2-propanol, 1-butanol, 2-butanol, t-butanol, 1-heptanol, 2-heptanol, 3-heptanol and 4-heptanol, and at least one of these compounds can be used, although the invention is not limited to these.

Particularly preferred among these are 1-propanol, 2-propanol, 1-butanol, 2-butanol and t-butanol from the standpoint of high solubility in the photosensitive composition, ready availability and safety.

The preferred ratio of component 1 and component 2 in the removing solution for photosensitive composition of the invention is 99-30 mass % of component 1 and 1-70 mass % of component 2. More preferred ratios for an improved drying speed and drying state are 90-30 mass % of component 1 and 10-70 mass % of component 2, when component 2 is an alkylene glycol monoalkyl ether, or 50-30 mass % of component 1 and 70-50 mass % of component 2, when component 2 is an alcohol.

The contents of component 1 and component 2 in the photosensitive composition of the invention are within the aforementioned ranges in order to result in satisfactory solubility of the resin and other components and dispersing removability of the pigments in the photosensitive composition.

The removing solution for photosensitive composition of the invention may also contain an acetic acid ester (component 3) in addition to the alicyclic ketone (component 1) and the at least one compound selected from alkylene glycol monoalkyl ethers and alcohols (component 2).

Component 3 to be added to the removing solution for photosensitive composition of the invention lowers the viscosity of the removing solution for photosensitive composition and improves the photosensitive composition removal rate, while also conferring suitable drying properties to the obtained removing solution and effectively preventing drying unevenness during the drying step after removal.

As specific examples of the acetic acid ester (component 3) to be used for the invention there may be mentioned ethyl acetate, n-propyl acetate, isopropyl acetate, n-butyl acetate, sec-butyl acetate, isobutyl acetate, amyl acetate, hexyl acetate and cyclohexyl acetate, and at least one of these compounds can be used, although the invention is not limited to these.

Particularly preferred among these are ethyl acetate, n-propyl acetate, isopropyl acetate, n-butyl acetate, n-amyl acetate, isoamyl acetate and sec-amyl acetate, from the standpoint of removability of the photosensitive composition, ready availability and safety.

When the removing solution for photosensitive composition of the invention contains component 1, component 2 and component 3, the preferred ratios for components 1, 2 and 3 are 80-30 mass % of component 1, 60-10 mass % of component 2 and 40-10 mass % of component 3, while more preferred ratios for an improved drying speed and drying state are 80-30 mass % of component 1, 40-10 mass % of component 2 and 40-10 mass % of component 3.

To the mixture of components 1 and 2 or the mixture of component 1, 2 and 3, there may optionally be added, as component 4, at least one of alkylene glycol monoalkyl ether carboxylic acid esters such as propylene glycol monomethyl ether acetate and ethlene glycol monomethyl ether acetate, 3-alkoxycarboxylic acid esters such as methyl 3-methoxypropionate and ethyl 3-ethoxypropionate, linear ketones such as acetone and methyl ethyl ketone, hydroxycarboxylic acid esters such as ethyl lactate, aromatic hydrocarbons such as toluene, xylene and trimethylbenzene, ethers such as diethylene glycol dimethyl ether, dipropylene glycol dimethyl ether, tetrahydrofuran, 1,4-dioxane and 1,3-dioxolane, and non-protonic polar solvents such as N-methyl-2-pyrrolidone, N,N-dimethylformamide, dimethyl sulfoxide and γ-butyrolactone. Component 4 also regulates the viscosity and drying properties of the obtained removing solution and improves the photosensitive composition removing effect.

The contents of components 1-3 in the photosensitive composition of the invention are within the aforementioned ranges in order to result in satisfactory removability of pigment-containing photosensitive compositions, while also helping to prevent drying irregularities during drying of the removing solution after removal treatment.

The following detailed explanation concerns a colored photosensitive resin composition for application of a removing solution of the invention.

The colored photosensitive resin composition for application of a removing solution of the invention is generally a pigment-containing colored photosensitive resin composition used in a process of forming the color filter of a liquid crystal device, organic EL device, image sensor or the like. Such colored photosensitive compositions are photosensitive compositions colored by addition of pigments, and generally they contain alkaline-developing film-forming substances, photosensitive substances, pigments and the like.

As film-forming substances to be included in the colored photosensitive composition there may be mentioned acrylic resins, novolac resins, polyimide resins and polyvinylphenol resins, but the removing solution of the invention is particularly suitable for removal of colored photosensitive compositions containing acrylic resins as film-forming substances. The acrylic resins used as film-forming substances are high-molecular polymers or copolymers with molecular weights of about 1000-500,000 which are alkali-soluble, and preferably are copolymers of carboxyl group-containing ethylenic unsaturated monomers and other ethylenic unsaturated monomers.

As photosensitive substances to be included in the colored photosensitive composition, when acrylic resins are used as film-forming substances, there may be mentioned hexaarylbiimidazole-based compounds, triazine-based compounds, aminoacetophenone-based compounds, combinations of sensitizing coloring matters and organic boron salt-based compounds, titanocene-based compounds, oxadiazole-based compounds and the like.

Pigments to be used in the colored photosensitive composition may be any pigments commonly used for manufacture of color filters, and these include black, yellow, red, blue and green colored organic or inorganic pigments, either alone or in any combinations of two or more. As specific examples of pigments there may be mentioned carbon black, acetylene black, lamp black, carbon nanotubes, graphite, iron black, iron oxide black pigment, aniline black, cyanine black, titanium black, C.I. Pigment Yellow 20, 24, 83, 86, 93, 109, 110, 117, 125, 137, 138, 139, 147, 148, 153, 154 and 166, C.I. Pigment Orange 36, 43, 51, 55, 59 and 61, C.I. Pigment Red 9, 97, 122, 123, 149, 168, 177, 180, 192, 215, 216, 217, 220, 223, 224, 226, 227, 228, 240 and 254, C.I. Pigment Violet 19, 23, 29, 30, 37, 40 and 50, C.I. Pigment Blue 15, 15:1, 15:4, 15:6, 22, 27, 60 and 64, C.I. Pigment Green 7, 10, 36 and 37, and C.I. Pigment Brown 23, 25 and 26.

The colored photosensitive composition may also contain an ethylenic unsaturated monomer in addition to the aforementioned film-forming substances, photosensitive substances and pigments. An ethylenic unsaturated monomer is a compound that polymerizes by radicals generated from a photopolymerization initiator upon irradiation with active light rays.

A colored photosensitive composition for application of a removing solution for photosensitive composition of the invention may also contain other components as appropriate, such as organic solvents, pigment dispersing agents, adhesiveness enhancers, leveling agents, developing enhancers, antioxidants, thermal polymerization inhibitors and the like.

The removing solution for photosensitive composition of the invention may be applied for removal of colored photosensitive compositions that have been coated or attached onto articles to be cleaned, and is particularly suitable for removal of colored photosensitive compositions prior to exposure to light. The colored photosensitive composition may have the solvent contained therein or may have the solvent already removed by evaporation.

The method for removal of the colored photosensitive composition may be a method in which the cleaning solution is sprayed from a nozzle or the like in a stream, liquid droplet or mist fashion onto the article to be cleaned having the colored photosensitive composition coated or attached thereto, or a method in which an article to be cleaned having the colored photosensitive composition attached thereto is dipped in the removing solution of the invention. For more efficient removal, this may be combined with physical cleaning such as ultrasonic irradiation or brushing.

The removing solution for photosensitive composition of the invention may be suitably used for removal of undesirable portions of an uncured colored photosensitive composition attached on the periphery, edges or back side of a substrate in the step of coating the colored photosensitive composition during manufacture of a color filter used for a liquid crystal device, an organic EL device, an image sensor or the like, or for removal of undesirable portions of an uncured colored photosensitive composition attached to all or a portion of a coating apparatus.

The removing solution for photosensitive composition of the invention may also be suitably applied for removal of an uncured colored photosensitive composition on the periphery, edges or back side of a substrate during coating of the colored photosensitive composition onto the substrate by spin coating, i.e. as a rinsing agent for edge rinsing or back rinsing, or for cleaning removal of a colored photosensitive composition that has splashed out into a cup during spin coating, i.e. for cup rinsing.

Other known methods for applying colored photosensitive compositions onto substrates other than spin coating include slit coating, wire bar coating and roll coating, but the removing solution for photosensitive composition of the invention may also be suitably used for removal of uncured portions of a colored photosensitive composition attached to surfaces of coating apparatus members or equipments such as slit nozzles, wire bars and printing plates.

Another aspect of the invention relates to a substrate from which uncured portions of a photosensitive composition have been removed using the aforementioned removing solution for photosensitive composition by the methods described above, and to apparatuses used for manufacture of liquid crystal devices, organic EL devices, image sensors and the like, as well as color filters obtained from such apparatuses.

The present invention will now be explained in greater detail through the following examples, with the understanding that the invention is in no way limited by the examples.

The cleaning property was evaluated on the following 3-level scale, based on visual observation of the dissolved condition of the colored photosensitive composition after immersion in the removing solution for 3 minutes.

Good—Completely removed

Fair—Partially dissolved

Poor—Virtually no dissolution

### Preparation Example 1 Preparation of Acrylic Copolymer

In a four-necked flask equipped with a dropping funnel, thermometer, condensation tube and stirrer there were charged 12.0 parts by mass of methacrylic acid (MA), 14.0 parts by mass of methyl methacrylate (MMA), 43.0 parts by mass of n-butyl methacrylate (BMA), 6.0 parts by mass of 2-hydroxyethyl acrylate (HEMA) and 225.0 parts by mass of ethylcellosolve acetate (EGA), and the four-necked flask was substituted with nitrogen for one hour. After heating to 90° C. with an oil bath, a mixture of 12.0 parts by mass of MA, 14.0 parts by mass of MMA, 43.0 parts by mass of BMA, 6.0 parts by mass of HEMA, 225.0 parts by mass of EGA and 3.2 parts by mass of 2,2′-azobisisobutyronitrile (AIBN) was added dropwise over a period of one hour. After subsequent polymerization for 3 hours, a mixture of 1.0 part by weight of AIBN and 15.0 parts by mass of EGA was added, and the mixture was heated to 100° C. for 1.5 hours of polymerization and then allowed to cool. The solid concentration of the acrylic copolymer obtained in this manner was 22.1 mass %, the acid value was 92 mgKOH/g and the mass weight-average molecular weight in terms of polystyrene as measured by GPC was 22,000.

### Preparation Example 2 Preparation of Colored Photosensitive Composition A: Black-Colored Photosensitive Composition

After mixing 30.0 parts by mass of the acrylic copolymer obtained in Preparation Example 1 (solid portion: 6.6 parts by mass), 5.0 parts by mass of EGA, 3.3 parts by mass of FLOWLEN DOPA-33 (trademark of Kyoeisha Chemical Co., Ltd., dispersing agent with solid concentration of 30 mass %) and 6.6 parts by mass of Special Black 4 (Degussa Corp., carbon black), the mixture was allowed to stand overnight. It was then stirred for one hour and passed four times through a triple roll mill (Model RIII-1 RM-2 by Kodaira Seisakusho Co., Ltd.). EGA was added to the obtained black ink to adjust the concentration, in order to obtain a black-colored composition with a solid concentration of 18.0 mass %.

To 100 parts by mass of the black-colored composition obtained in this manner there were further added 4.4 parts by mass of dipentaerythritol hexaacrylate, 2.2 parts by mass of 2-(4-methoxyphenyl)-4,6-bis(trichloromethyl)-s-triazine and 25 parts by mass of EGA, and the mixture was thoroughly stirred to obtain colored photosensitive composition A.

### Preparation Example 3 Preparation of Colored Photosensitive Composition B: Green-Colored Photosensitive Composition

After mixing 30.0 parts by mass of the acrylic copolymer obtained in Preparation Example 1 (solid portion: 6.6 parts by mass), 5.0 parts by mass of EGA, 3.3 parts by mass of FLOWLEN DOPA-33 (trademark of Kyoeisha Chemical Co., Ltd., dispersing agent with solid concentration of 30 mass %) and 6.6 parts by mass of Pigment Green 36, the mixture was allowed to stand overnight. It was then stirred for one hour and passed four times through a triple roll mill (Model RIII-1 RM-2 by Kodaira Seisakusho Co., Ltd.). EGA was added to the obtained green ink to adjust the concentration, in order to obtain a green-colored composition with a solid concentration of 18.0 mass %.

To 100 parts by mass of the green-colored composition obtained in this manner there were further added 4.4 parts by mass of dipentaerythritol hexaacrylate, 0.7 part by weight of 4,4′-bis(N,N-diethylamino)benzophenone, 2.3 parts by mass of 2,2′-bis(o-chlorophenyl)-4,4′-5,5′-tetraphenyl-1,2′-biimidazole, 3.8 parts by mass of trimethylolpropane tristhiopropionate and 42 parts by mass of EGA, and the mixture was thoroughly stirred to obtain colored photosensitive composition B.

### Preparation Example 4 Preparation of Colored Photosensitive Composition C: Red-Colored Photosensitive Composition

After mixing 30.0 parts by mass of the acrylic copolymer obtained in Preparation Example 1 (solid portion: 6.6 parts by mass), 5.0 parts by mass of EGA, 3.3 parts by mass of FLOWLEN DOPA-33 (trademark of Kyoeisha Chemical Co., Ltd., dispersing agent with solid concentration of 30 mass %) and 6.6 parts by mass of Pigment Red 177, the mixture was allowed to stand overnight. It was then stirred for one hour and passed four times through a triple roll mill (Model RIII-1 RM-2 by Kodaira Seisakusho Co., Ltd.). EGA was added to the obtained red ink to adjust the concentration, in order to obtain a red-colored composition with a solid concentration of 18.0 mass %. To 100 parts by mass of this colored composition there were further added 4.4 parts by mass of dipentaerythritol hexaacrylate, 3.0 parts by mass of Irgacure 369 (Ciba Specialty Chemicals), 3.8 parts by mass of trimethylolpropane tristhiopropionate and 42 parts by mass of EGA, and the mixture was thoroughly stirred to obtain colored photosensitive composition C.

### Example 1

One drop of each of the colored photosensitive compositions A-C prepared in Preparation Examples 2-4 was dropped onto a glass plate (28 mm×76 mm) and allowed to dry at room temperature for 24 hours.

This was immersed and allowed to stand for 3 minutes in a removing solution comprising a mixture of 99 g of cyclohexanone and 1 g of propylene glycol monomethyl ether, for cleaning removal of the colored photosensitive composition coated on the surface. The results are shown in Table 1.

### Examples 2-18

### Comparative Examples 1-9

The colored photosensitive compositions were removed in the same manner as Example 1, using removing solutions having the compositions listed in Table 1. The results are also shown in Table 1.

The drying property was evaluated on the following 3-level scale based on visual observation of the state of drying of the removing solution after coated onto a test piece.

Good—Evenly dried on test piece

Fair—Unevenly dried on test piece (fine droplets observed)

Poor—Aggregated droplets observed on test piece

### Example 19

A 10 cm-square test piece (SUS304: electropolished product) was set in a spin coater (Model 1H-DX (product of Mikasa Co., Ltd.) and 2 ml of the same removing solution as used in Example 1 was dropped onto it. After coating the removing solution (400 rpm, 5 sec), the state of drying on the test piece was observed in the horizontal position as set in the coater. The result is shown in Table 2.

### Examples 20-36

### Comparative Examples 10-18

The state of drying was observed in the same manner as Example 19, using removing solutions having the compositions listed in Table 2. The results are also shown in Table 2.

TABLE 1

| | | Cleaning solution composition | | | | | Cleaning property | | |
|---|---|---|---|---|---|---|---|---|---|
| | | (mass %) | | | | | Colored photosensitive | | |
| | | Component 1 | | Component 2 | | Component 3 | composition | | |
| | | CYA | CYP | PM | BOH | BAC | A (Black) | B (Green) | C (Red) |
| Example | 1 | 99 | | 1 | | | good | good | good |
| | 2 | 99 | | | 1 | | good | good | good |
| | 3 | 70 | | 30 | | | good | good | good |
| | 4 | 70 | | | 30 | | good | good | good |
| | 5 | 50 | | 50 | | | good | good | good |
| | 6 | 50 | | | 50 | | good | good | good |
| | 7 | 30 | | 70 | | | good | good | good |
| | 8 | 30 | | | 70 | | good | good | good |
| | 9 | | 70 | 30 | | | good | good | good |
| | 10 | 30 | 30 | 40 | | | good | good | good |
| | 11 | 60 | | 20 | 20 | | good | good | good |
| | 12 | 80 | | 10 | | 10 | good | good | good |
| | 13 | 60 | | 20 | | 20 | good | good | good |
| | 14 | 40 | | 40 | | 20 | good | good | good |
| | 15 | 30 | | 60 | | 10 | good | good | good |
| | 16 | 30 | | 30 | | 40 | good | good | good |
| | 17 | 60 | | | 20 | 20 | good | good | good |
| | 18 | 40 | | | 40 | 20 | good | good | good |
| Comp. | 1 | 100 | | | | | good | fair | good |
| Ex. | 2 | | | 100 | | | poor | poor | fair |
| | 3 | | | | | 100 | poor | poor | poor |
| | 4 | 20 | | 80 | | | poor | fair | good |
| | 5 | 20 | | | 80 | | poor | poor | poor |
| | 6 | 50 | | | | 50 | fair | fair | fair |
| | 7 | | | 50 | | 50 | poor | poor | poor |
| | 8 | 30 | | 20 | | 50 | poor | fair | fair |
| | 9 | 20 | | 60 | | 20 | fair | fair | good |

TABLE 2

| | | Cleaning solution composition (mass %) | | | | | |
|---|---|---|---|---|---|---|---|
| | | Component | | Component | | Component | |
| | | 1 | | 2 | | 3 | Drying |
| | | CYA | CYP | PM | BOH | BAC | state |
| Example | 19 | 99 | | 1 | | | good |
| | 20 | 99 | | | 1 | | poor |
| | 21 | 70 | | 30 | | | good |
| | 22 | 70 | | | 30 | | poor |
| | 23 | 50 | | 50 | | | good |
| | 24 | 50 | | | 50 | | fair |
| | 25 | 30 | | 70 | | | good |
| | 26 | 30 | | | 70 | | good |
| | 27 | | 70 | 30 | | | fair |
| | 28 | 30 | 30 | 40 | | | fair |
| | 29 | 60 | | 20 | 20 | | fair |
| | 30 | 80 | | 10 | | 10 | good |
| | 31 | 60 | | 20 | | 20 | good |
| | 32 | 40 | | 40 | | 20 | good |
| | 33 | 30 | | 60 | | 10 | fair |
| | 34 | 30 | | 30 | | 40 | good |
| | 35 | 60 | | | 20 | 20 | fair |
| | 36 | 40 | | | 40 | 20 | fair |
| Comp. | 10 | 100 | | | | | poor |
| Ex. | 11 | | | 100 | | | fair |
| | 12 | | | | | 100 | good |
| | 13 | 20 | | 80 | | | good |
| | 14 | 20 | | | 80 | | good |
| | 15 | 50 | | | | 50 | good |
| | 16 | | | 50 | | 50 | good |
| | 17 | 30 | | 20 | | 50 | good |
| | 18 | 20 | | 60 | | 20 | good |

CYA: Cyclohexanone
CYP: Cyclopentanone
PM: Propylene glycol monomethyl ether
BOH: 1-Butanol
BAC: n-Butyl acetate

### INDUSTRIAL APPLICABILITY

The present invention is industrially advantageous as it provides a removing solution for photosensitive composition that is useful for removal of a residual pigment-containing photosensitive composition film on the periphery, edges or back side of a substrate during the step of forming a photosensitive composition film in the manufacture of a liquid crystal device, organic EL device, image sensor or the like, or for removal of a pigment-containing photosensitive composition attached to the surface of an apparatus member or an equipment.

1. A removing solution for photosensitive composition which is a removing solution for a photosensitive composition containing a pigment, characterized by comprising
(1) 99-30 mass % of an alicyclic ketone and
(2) 1-70 mass % of at least one compound selected from alkylene glycol monoalkyl ethers and alcohols.

2. removing solution for photosensitive composition which is a removing solution for a photosensitive composition containing a pigment, characterized by comprising
(1) 80-30 mass % of an alicyclic ketone,
(2) 60-10 mass % of at least one compound selected from alkylene glycol monoalkyl ethers and alcohols and
(3) 40-10 mass % of an acetic acid ester.

3. A removing solution for photosensitive composition according to claim 1, wherein the alicyclic ketone is one or more selected from the group consisting of cyclohexanone, cyclopentanone and methylcyclohexanone.

4. A removing solution for photosensitive composition according to claim 1, wherein the alkylene glycol monoalkyl ether is one or more selected from the group consisting of ethylene glycol monomethyl ether, ethylene glycol monoethyl ether, diethylene glycol monomethyl ether, diethylene glycol monoethyl ether, propylene glycol monomethyl ether, propylene glycol monoethyl ether, dipropylene glycol monomethyl ether, 3-methoxybutanol and 3-methyl-3-methoxybutanol, and the alcohol is one or more selected from the group consisting of 1-propanol, 2-propanol, 1-butanol, 2-butanol and t-butanol.

5. A removing solution for photosensitive composition according to claim 2, wherein the acetic acid ester is one or more selected from the group consisting of ethyl acetate, n-propyl acetate, isopropyl acetate, n-butyl acetate, n-amyl acetate, isoamyl acetate and sec-amyl acetate.

6. A removing solution for photosensitive composition according to claim 1, which is used for removal of an acrylic photosensitive composition containing a pigment.

7. A removing solution for photosensitive composition according to claim 1, which is used for removal of a photosensitive composition containing a pigment prior to exposure to light.

8. An apparatus in which a photosensitive composition containing a pigment is removed using a removing solution for photosensitive composition according to claim 1.

9. A color filter obtained by an apparatus according to claim 8.

10. A device equipped with a color filter according to claim 9.

11. A substrate that has been treated for removal of a photosensitive composition containing a pigment using a removing solution for photosensitive composition according to claim 1.

12. A removing solution for photosensitive composition according to claim 2, wherein the alicyclic ketone is one or more selected from the group consisting of cyclohexanone, cyclopentanone and methylcyclohexanone.

13. A removing solution for photosensitive composition according to claim 2, wherein the alkylene glycol monoalkyl ether is one or more selected from the group consisting of ethylene glycol monomethyl ether, ethylene glycol monoethyl ether, diethylene glycol monomethyl ether, diethylene glycol monoethyl ether, propylene glycol monomethyl ether, propylene glycol monoethyl ether, dipropylene glycol monomethyl ether, 3-methoxybutanol and 3-methyl-3-methoxybutanol, and the alcohol is one or more selected from the group consisting of 1-propanol, 2-propanol, 1-butanol, 2-butanol and t-butanol.

14. A removing solution for photosensitive composition according to claim 2, which is used for removal of an acrylic photosensitive composition containing a pigment.

15. A removing solution for photosensitive composition according to claim 2, which is used for removal of photosensitive composition containing a pigment prior to exposure to light.

16. An apparatus in which a photosensitive composition containing a pigment is removed using a removing solution for photosensitive composition according to claim 2.

17. A color filter obtained by an apparatus according to claim 16.

18. A device equipped with a color filter according to claim 17.

19. A substrate that has been treated for removal of a photosensitive composition containing a pigment using a removing solution for photosensitive composition according to claim 2.
